(19) United States
(12) Patent Application Publication
(10) Pub. No.: US 2014/0211441 A1
(43) Pub. Date: Jul. 31, 2014

(54) WIRELESS APPARATUS AND METHOD FOR MANUFACTURING SAME

(71) Applicant: PANASONIC CORPORATION, Osaka (JP)

(72) Inventor: Takayuki Tsukizawa, Kanagawa (JP)

(21) Appl. No.: 14/130,581

(22) PCT Filed: Oct. 19, 2012
(86) PCT No.: PCT/JP2012/006727

§ 371 Date: Jan. 2, 2014

(30) Foreign Application Priority Data
Nov. 8, 2011 (JP) 2011-244970

(51) Int. Cl. H05K 1/02; H05K 3/30; H05K 1/11

(52) U.S. Cl. CPC H05K 1/0237; H05K 1/11; H05K 3/30
USPC 361/783; 29/593

(57) ABSTRACT

A wireless apparatus has a board, a power amplifier high-frequency IC chip, and a process variations detector. The process variations detector monitors a circuit characteristic variation amount due to process variations. An underfill having a parameter value calculated using the monitored circuit characteristic variation amount is applied between the board and the high-frequency IC chip and the mounting board. As a result, the wireless apparatus exhibits a desired circuit characteristic even with process variations and influence of the underfill.

### TECHNICAL FIELD

This disclosure relates to a wireless apparatus and a method for manufacturing the same and, more particularly, to a wireless apparatus incorporating a high-frequency circuit.

### BACKGROUND ART

Mainly in microwave and millimeter wave bands, the flip-chip mounting is used widely in which a high-frequency IC chip is mounted on a mounting board using gold (Au) or solder bumps, for example. The flip-chip mounting can reduce connection losses because the high-frequency IC chip can be connected to the mounting board so as to be set at a short (shortest) distance.

An example will be described with reference to FIG. 17. A ceramic board, for example, is used as a mounting board 1 which is a base board of a module and a circuit 5 of, for example, an amplifier MMIC (monolithic microwave integrated circuit) chip 4 which is a high-frequency IC chip is connected to input/output terminals 2 and 3 by bumps 6. Furthermore, for reinforcement of the connections or sealing of the MMIC chip 4, the space between the mounting board 1 and the MMIC chip 4 is filled with resin which serves as an underfill 7.

However, when the above-mentioned underfill 7 is applied, characteristic degradations occur that the characteristic of the MMIC chip 4 is shifted to the low-frequency side due to increased parasitic capacitances and the gain is lowered.

In view of the above, a microwave/millimeter wave circuit device that is less prone to be affected by an underfill used in flip-chip mounting has been proposed (refer to Patent document 1).

FIG. 18 shows a flip-chip-mounted microwave/millimeter wave circuit device as a conventional example which is described in Patent document 1. In the microwave/millimeter wave circuit device, an MMIC chip 4 is opposed to and flip-chip-mounted on a mounting board 1. The MMIC chip 4 is provided with an insulator wall 11 which encloses a circuit 5 and an underfill 7 is applied outside the insulator wall 11. With this form, since the insulator wall 11 is formed so as to enclose the circuit (main part), no resin goes to under the circuit 5 even when the underfill 7 is applied and little change occurs in the circuit characteristics.

### PRIOR ART DOCUMENTS

### Patent Documents

Patent document 1: JP-A-2000-269384

### SUMMARY OF THE INVENTION

### Problems to be Solved by the Invention

However, in the flip-chip-mounted microwave/millimeter wave circuit device described in Patent document 1, it is necessary to provide the MMIC chip 4 with the insulator wall 11 so that it encloses the circuit 5 and to charge the underffl±7 outside the insulator wall 11. Therefore, in the structure of Patent document 1, a cavity is formed under the circuit 5 of the MMIC chip 4 and hence it is difficult to obtain sufficient mounting strength.

Furthermore, if a variation occurs in the characteristics of high-frequency IC chips due to process variations, the circuit characteristics may be varied and the module performance may be degraded.

That is, there is a problem that although characteristic degradations due to flip-chip mounting can be suppressed, characteristic degradations due to process variations of the high-frequency IC chip remain to cause reduction of the module production yield.

The present disclosure has been made in view of the above circumstances, and an object of the disclosure is to provide a wireless apparatus in which sufficient mounting strength is secured and characteristic degradations are suppressed, as well as a method for manufacturing the wireless apparatus.

### Means for Solving the Problems

In view of the above, this disclosure provides a wireless apparatus comprising a mounting board; a high-frequency IC chip which is flip-chip-mounted on the mounting board; and an underfill which is applied between the high-frequency IC chip and the mounting board, wherein the high-frequency IC chip comprises a device unit which constitutes a main circuit and a process variations detector for detecting a process variation of the high-frequency IC chip; and that the underfill has a parameter value that corresponds to the detected process variation.

The disclosure includes the above wireless apparatus as further characterized in that the process variations detector functions as part of the device unit.

The disclosure includes the above wireless apparatus as further characterized in that the process variations detector is separated from the device unit in the high-frequency IC chip.

The disclosure includes the above wireless apparatus as further characterized in that the process variations detector is formed by using a transistor.

The disclosure includes the above wireless apparatus as further characterized in that the process variations detector is formed by using a ring oscillator.

The disclosure includes the above wireless apparatus as further characterized in that the parameter value of the underfill is a relative permittivity value of a material that is applied as the underfill.

The disclosure includes the above wireless apparatus as further characterized in that the parameter value of the underfill is a distance between the high-frequency IC chip and the mounting board.

The disclosure includes the above wireless apparatus as further characterized in that the high-frequency IC chip is connected to the mounting board via bumps, and that the bumps are arranged asymmetrically on the high-frequency IC chip.

The disclosure includes the above wireless apparatus as further characterized in that the underfill which is applied between the high-frequency IC chip and the mounting board varies in thickness in an area where the high-frequency IC chip is flip-chip-mounted.

The disclosure includes the above wireless apparatus as further characterized in that the process variations detector uses PCM (process control monitor) data.

The disclosure includes the above wireless apparatus as further characterized in that the process variation is represented by a value that was measured before applying of the underfill.

The disclosure also provides a manufacturing method characterized by comprising the steps of manufacturing a high-frequency IC chip having a process variations detector and a device unit that constitutes a main circuit; detecting a process variation of the high-frequency IC chip using the process variations detector; and mounting the high-frequency IC chip on a mounting board by applying an underfill having a parameter value that corresponds to data detected by the detecting step.

### Advantages of the Invention

This disclosure makes it possible to provide a wireless apparatus in which sufficient mounting strength is secured and characteristic degradations are suppressed, as well as a method for manufacturing the wireless apparatus.

### BRIEF DESCRIPTION OF THE DRAWINGS

FIG. 1 illustrates a wireless apparatus including a power amplifier which corresponds to a microwave/millimeter wave circuit according to a first embodiment of this disclosure.

FIG. 2 is an equivalent circuit diagram of the power amplifier which corresponds to the microwave/millimeter wave circuit according to the first embodiment of the disclosure.

FIG. 3 is an equivalent circuit diagram of a MOSFET which constitutes a process variations detector provided in the power amplifier.

FIG. 4 is a graph showing how the characteristic of the input reflection coefficient and the output reflection coefficient of the power amplifier varies when its threshold voltage Vth varies due to process variations (without an underfill).

FIG. 5 is a graph showing how the characteristic of the input reflection coefficient and the output reflection coefficient of the power amplifier varies depending on whether or not resin is applied as an underfill.

FIG. 6 shows a gate voltage vs. drain current characteristic of the MOS transistor shown in FIG. 3.

FIG. 7 shows how the notch frequency of the reflection coefficients varies with the relative permittivity Er of a resin.

FIG. 8 shows how the notch frequency varies with the distance between a mounting board and a power amplifier IC chip.

FIG. 9 shows how the notch frequency of the reflection coefficients, that is, the frequency at which the reflection coefficients are minimized, is varied by process variations or influence of the underfill.

FIG. 10 is a flowchart of a mounting process which includes selection of an underfill for compensating for a circuit characteristic variation due to process variations.

FIG. 11 shows a process variations detector of a wireless apparatus according to a second embodiment of the disclosure.

FIG. 12(a) is a bottom view of a power amplifier IC chip which is part of a wireless apparatus according to a third embodiment of the disclosure, FIG. 12(b) is a sectional view showing a mounted state of the wireless apparatus according to the third embodiment.

FIG. 13 shows a modification of the power amplifier IC chip of the wireless apparatus according to the third embodiment of the disclosure.

FIG. 14 shows another modification of the power amplifier IC chip of the wireless apparatus according to the third embodiment of the disclosure.

FIG. 15 shows a further modification of the power amplifier IC chip of the wireless apparatus according to the third embodiment of the disclosure.

FIG. 16 shows an example wafer for forming a power amplifier IC chip of a wireless apparatus according to the fourth embodiment of the disclosure.

FIG. 17 shows an example conventional wireless apparatus.

FIG. 18 shows an example conventional microwave/millimeter wave circuit device.

### MODE FOR CARRYING OUT THE INVENTION

### Embodiment 1

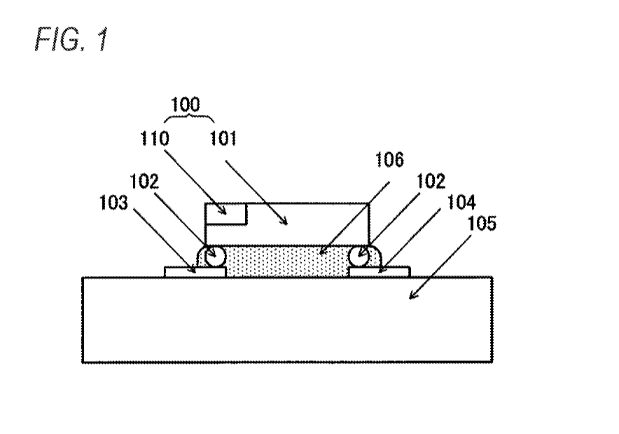

FIG. 1 shows an example configuration of a wireless apparatus (module) including a power amplifier according to a first embodiment of the present disclosure, which corresponds to a microwave/millimeter wave circuit.

The wireless apparatus according to the first embodiment employs a power amplifier high-frequency IC chip 100 as a high-frequency IC chip. A main circuit 101 and a process variations detector 110 which constitutes a variations detecting circuit are integrated into the power amplifier high-frequency IC chip 100 which constitutes a power amplifier.

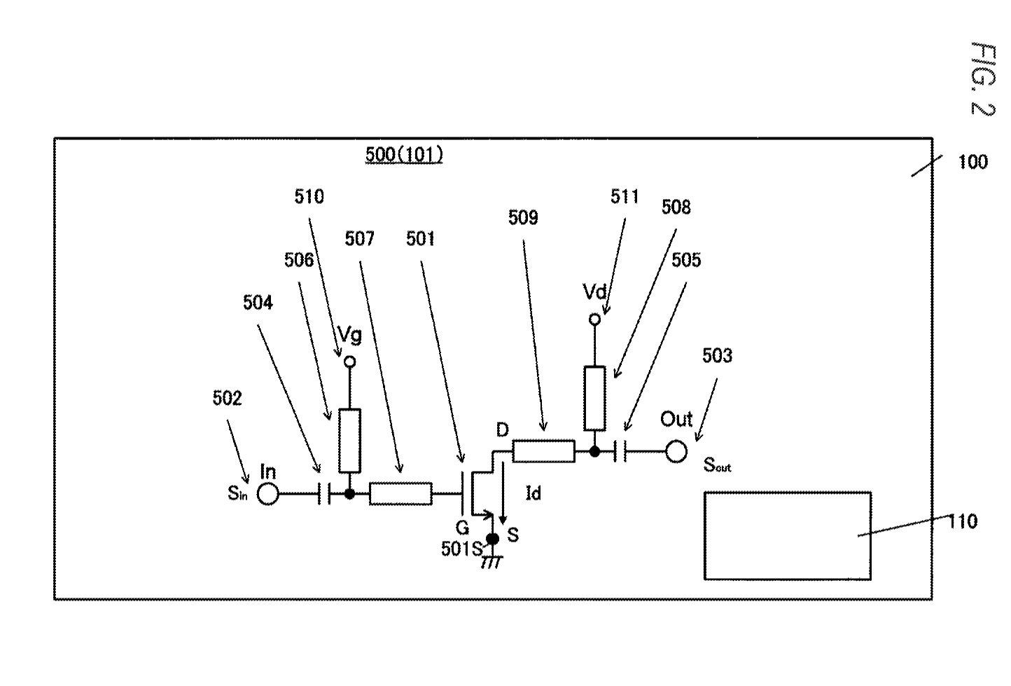

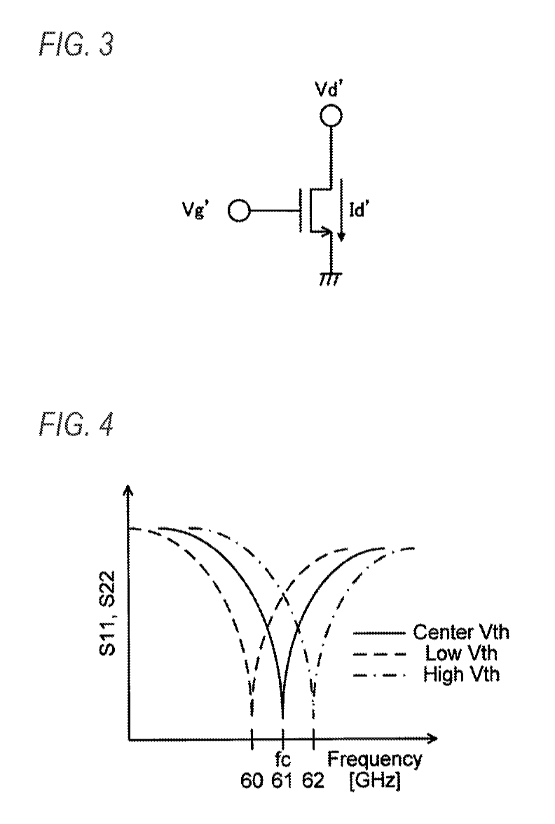

FIG. 1 illustrates the wireless apparatus incorporating the power amplifier high-frequency IC chip 100 having the process variations detector 110 according to the first embodiment. FIG. 2 is an equivalent circuit diagram of the power amplifier high-frequency IC chip 100. FIG. 3 is an equivalent circuit diagram of a MOSFET which constitutes the process variations detector 110 provided in the power amplifier high-frequency IC chip.

Before the description of the power ampler high-frequency IC chip according to the first embodiment of the disclosure, a description will be made of how the power amplifier high-frequency IC chip corresponding to a microwave/millimeter wave circuit operates. Whereas the main circuit 101 of the power amplifier high-frequency IC chip 100 is a common circuit, in the embodiment, as shown in FIGS. 1 and 2, the process variations detector 110 is integrated together with a device unit 500 which constitutes the main circuit 101.

FIG. 2 shows the equivalent circuit of the power amplifier high-frequency IC chip corresponding to the microwave/millimeter wave circuit according to the first embodiment of the disclosure. In the power amplifier, an input terminal 502 and an output terminal 503 of the device unit 500 which constitutes the main circuit 101 are provided with a DC block capacitor 504 and a DC block capacitor 505, respectively.

Input matching transmission lines 506 and 507 are provided between the gate G of a power amplification transistor 501 and the input terminal 502, and output matching transmission lines 508 and 509 are provided between its drain D and an output terminal 503.

The series connection of the input matching transmission lines 506 and 507 is provided between a gate voltage terminal 510 for the transistor 501 and the gate G of the power amplification transistor 501. The series connection of the output matching transmission lines 508 and 509 is provided between a drain voltage terminal 511 for the power amplification transistor 501 and the drain D of the power amplification transistor 501.

An input signal Sin is input to the input terminal 502 and then input to the gate G of the transistor 501 via the DC block capacitor 504, and transmission line 507. A gate voltage is applied to the gate G which is connected to the gate voltage terminal 510 via the transmission lines 506 and 507. The source S of the transistor 501 is grounded.

A drain voltage Vd is applied to the transistor 501's drain D which is connected to the drain voltage terminal 511 via the transmission lines 508 and 509. An output signal Sout is output from the connecting point of the transmission lines 508 and 509 and then output from the output terminal 503 via the DC block capacitor 505. A drain current flows through the power amplification transistor 501, and the source S of the transistor 501 is provided with a source terminal 501S.

In general, transistors vary in threshold voltage Vth due to process variations. The drain current Id increases as the threshold voltage Vth decreases, and the drain current Id decreases as the threshold voltage Vth increases. The maximum operation frequency fmax of a transistor increases as the threshold voltage Vth decreases, and the maximum operation frequency fmax decreases as the threshold voltage Vth increases. A transistor is given better high-frequency characteristics when its maximum operation frequency fmax is higher.

Therefore, also as for a MOSFET that constitutes the process variations detector shown in FIG. 3, its threshold voltage Vth varies due to process variations; the drain current Id′ increases as the threshold voltage Vth decreases and the drain current Id′ decreases as the threshold voltage Vth increases.

FIG. 4 is a graph showing a relationship between each of the input reflection coefficient S11 and the output reflection coefficient S22 of the power amplifier high-frequency IC chip 100 with the threshold voltage Vth as a parameter. The threshold voltage Vth varies due to process variations. The vertical axis represents the reflection coefficient and the horizontal axis represents the frequency (GHz).

The solid line represents a case with an ideal threshold voltage (no process variations); in the following description, this case will be referred to as a case that the threshold voltage Vth is at the center. The broken line represents a case with a threshold voltage that is lower than the ideal one (process variations occurred); this case will be referred to as a case that the threshold voltage Vth is low. The chain line represents a case with a threshold voltage that is higher than the ideal one (process variations occurred); this case will be referred to as a case that the threshold voltage Vth is high.

Although in FIG. 4 the reflection coefficients S11 and S22 are on the same axis, they may have different characteristics.

As the threshold voltage Vth decreases, the drain current Id increases and, as a result, the parasitic capacitances of the transistor 501 increase. For example, even if the transistor 501 is designed so that the notch frequency (reflection coefficient minimizing position) of the input reflection coefficient S11 and the output reflection coefficient 822 is set at a desired frequency fc in the case where the threshold voltage Vth is at the center, the notch position of the input reflection coefficient S11 and the output reflection coefficient S22 is shifted to the low-frequency side by the parasitic capacitances of the transistor 501 if the threshold voltage Vth decreases due to process variations.

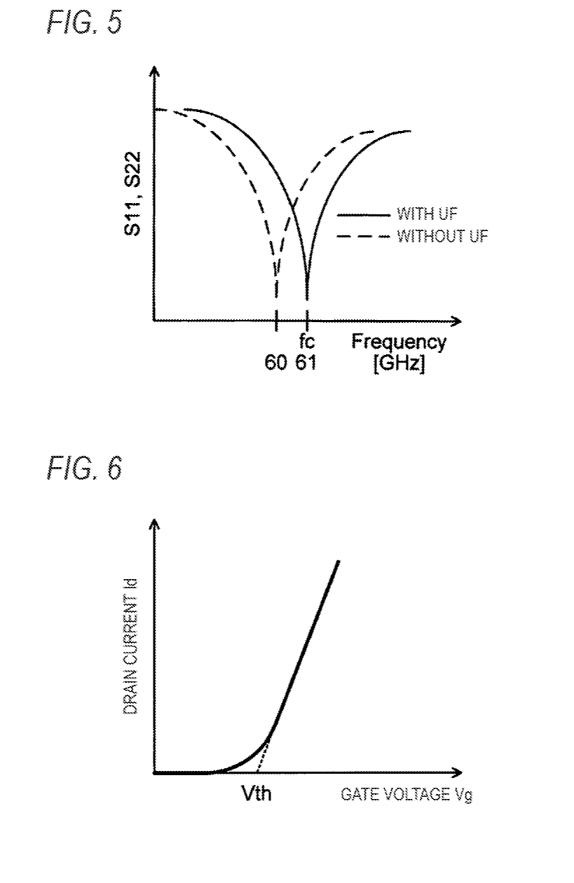

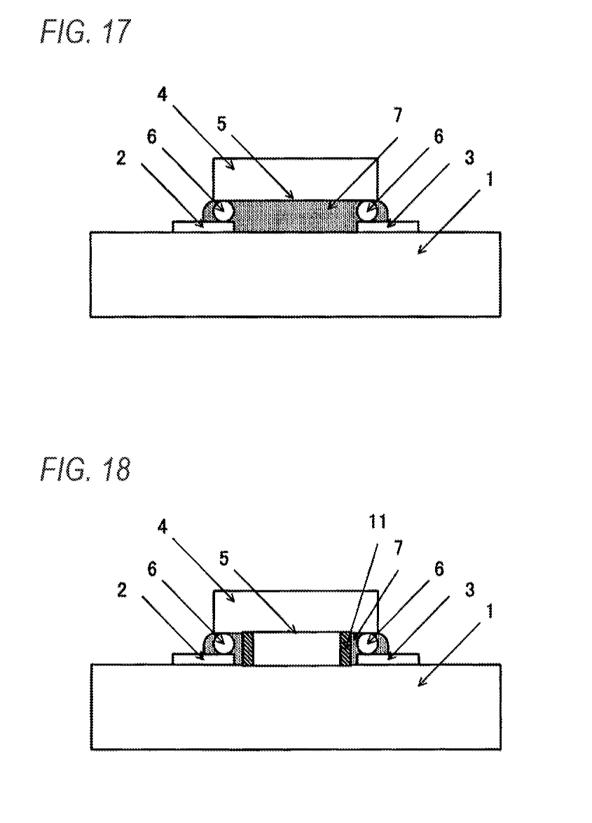

FIG. 5 is a graph is a graph showing a relationship between each of the input reflection coefficient 811 and the output reflection coefficient S22 of the power amplifier high-frequency IC chip 100 with presence/absence of an underfill 106 as a parameter. FIG. 5 shows a relationship in a case that the power amplifier high frequency IC chip (the power amplifier IC chip incorporating a power amplifier) 100 shown in FIG. 2 is flip-chip-mounted on a mounting board 105 and the space between the power amplifier IC chip and the mounting board 105 is filled with resin (underfill (UF) 106) in the manner shown in FIG. 17 and a relationship in a case that resin is not applied.

Since in general the resin used as an underfill is a dielectric, it serves to increase parasitic capacitances. The solid line represents a characteristic of the reflection coefficients S11 and S22 without an underfill (UF), and the broken line represents a characteristic of the reflection coefficients 811 and 822 in the case that flip-chip mounting is done and an underfill (UF) is used.

As seen from FIG. 5, even if the power amplifier transistor 501 is designed so that the notch frequency of the input reflection coefficient S11 and the output reflection coefficient S22 is set at the frequency fc in the case where the threshold voltage Vth is at the center and an underfill (UF) is not used, the notch position of the reflection coefficients 811 and 822 is shifted to the low-frequency side by the parasitic capacitances that are influenced by the underfill.

In FIG. 5, the relative permittivity of the underfill is equal to 3.3 and the distance between the mounting board and the power amplifier IC chip is longer than or equal to 20 μm (see FIG. 8).

This disclosure has been made paying attention to the above, and the first embodiment is to solve the problem that the frequency characteristic is degraded by influence of an underfill in flip-chip mounting and by process variations in a wireless apparatus incorporating a high-frequency circuit.

To solve the above problem, process variations are detected using a transistor that constitutes the process variations detector 110 of the power amplifier IC chip concerned. A desired frequency characteristic is obtained by applying an underfill that satisfies a material or charge amount condition for compensating for a detection result.

Now, the description of the wireless apparatus according to the first embodiment of the disclosure is restarted. FIG. 1 shows the configuration of the wireless apparatus according to the first embodiment of the disclosure. The wireless apparatus is equipped with the power amplifier high-frequency IC chip 100 corresponding to a microwave/millimeter wave circuit, bumps 102, input terminals 103, output terminals 104, a mounting board 105, an underfill 106, and the process variations detector 110. The power amplifier high-frequency IC chip 100 is connected, via the bumps 102, to the input terminals 103 and the output terminals 104 formed on the mounting board 105. The space between the power amplifier high-frequency IC chip 100 and the mounting board 105 is filled with resin which is the underfill 106. Furthermore, the power amplifier high-frequency IC chip 100 has the process variations detector 110 for detecting process variations of the power amplifier high-frequency IC chip 100.

FIG. 3 is an equivalent circuit diagram of a MOS transistor which is an example of the process variations detector 110. FIG. 6 shows a gate voltage vs. drain current characteristic of the MOS transistor shown in FIG. 3. The process variations detector of FIG. 3 is formed using the MOS transistor. In general, the drain current Id′ flows when the gate voltage Vg′ shown in FIG. 3 is higher than the threshold voltage Vth′. The threshold voltage Vth′ of the MOS transistor which constitutes the process variations detector 110 can be known by measuring the gate voltage vs. drain current characteristic as shown in FIG. 6.

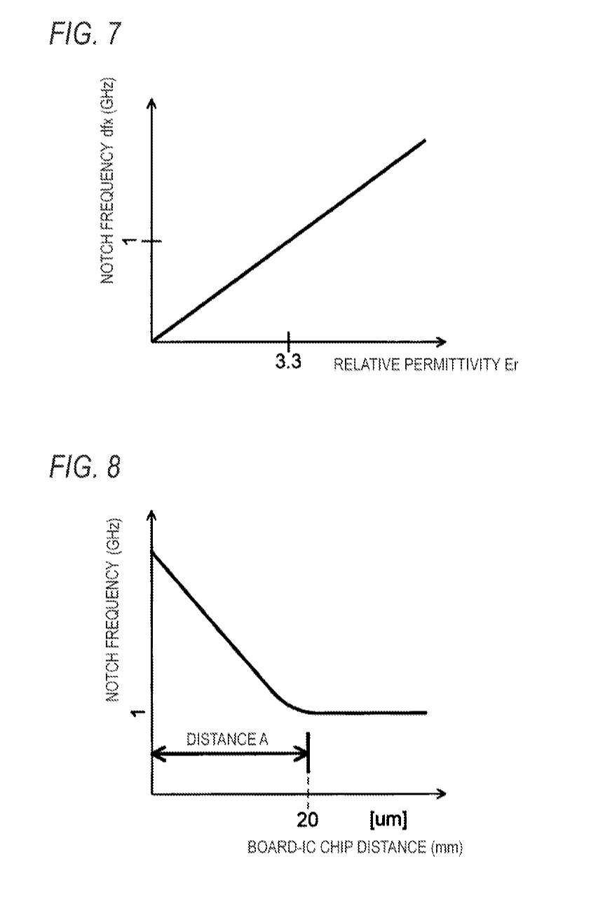

On the other hand, as shown in FIG. 5, the frequency (hereinafter referred to as the notch frequency) corresponding to the position of the notch of the reflection coefficient, that is, the reflection coefficient minimizing frequency, decreases when resin is applied as an underfill in flip-flop mounting. As shown in FIG. 7, the notch frequency variation amount depends on the relative permittivity Er of the resin.

FIG. 7 shows how the notch frequency of the reflection coefficients S11 and S12, that is, the frequency at which the reflection coefficients are minimized, varies with the relative permittivity Er. As the relative permittivity Er increases, the parasitic capacitances increase and the notch frequency decreases. The relative permittivity is changed by changing the material or composition of the resin that is applied as the underfill. The notch frequency variation amount can be adjusted in this manner.

FIG. 8 shows how the notch frequency varies with the distance between the mounting board 105 and the power amplifier high-frequency IC chip 100 shown in FIG. 1. When the distance between the mounting board 105 and the power amplifier high-frequency IC chip 100 is small, the parasitic capacitances are large and the notch frequency varies to a large extent.

When the distance between the mounting board 105 and the power amplifier high-frequency IC chip 100 is long, the parasitic capacitances do not vary with the distance and the notch frequency variation amount is kept constant. Let a distance between the mounting board 105 and the power amplifier high-frequency IC chip 100 within which the notch frequency variation amount is proportional to the distance between the mounting board 105 and the power amplifier high-frequency IC chip 100 be called a distance A. The notch frequency variation amount can be controlled by changing the distance A. For example, the notch frequency variation amount can be controlled by adjusting the underfill charge amount.

When the power amplifier high-frequency IC chip 100 is flip-chip-mounted on the mounting board 105, pressure is applied to the power amplifier high-frequency IC chip 100 from above. The distance A can be changed by changing the pressure applied from above.

FIG. 9 shows how the notch frequency of the input reflection coefficient S11 and the output reflection coefficient S22 is varied by process variations or influence of the underfill.

The variation due to process variations occurs through a variation of the threshold voltage Vth of the transistor. The variation due to influence of the underfill is either a variation due to a variation of the relative permittivity Er of the underfill or a variation due to a variation of the distance between the mounting board 105 and the power amplifier high-frequency IC chip 100 (this variation occurs within the distance A and is proportional to the distance between the mounting board 105 and the power amplifier high-frequency IC chip 100).

Like the one shown in FIGS. 4 and 5, the notch frequency fc shown in FIG. 9 is a notch position of the input reflection coefficient S11 and the output reflection coefficient S22 in the case where the threshold voltage Vth of the MOS transistor is at the center and no underfill (UF) is used. The notch frequency varies due to process variations in a range X, and the upper limit and the lower limit of the range are represented by fxh and fxl, respectively. The notch frequency varies due to influence of the underfill in a range Y, and the upper limit and the lower limit of the range are represented by fyh and fyl, respectively.

The notch frequency fc without an underfill is identical to the upper limit fyh of the notch frequency range corresponding to the influence of the underfill. The range of variation due to process variations plus the influence of the underfill is from fyl to fxh, and a desired frequency ft should fall within this range. Let dfx and dfy represent the frequency variation amount due to process variations and the frequency variation amount due to the influence of the underfill, respectively; then the frequency fz that is affected by both factors is given by fz=ft+dfx dfy. Such a frequency fz should be employed as a desired frequency ft.

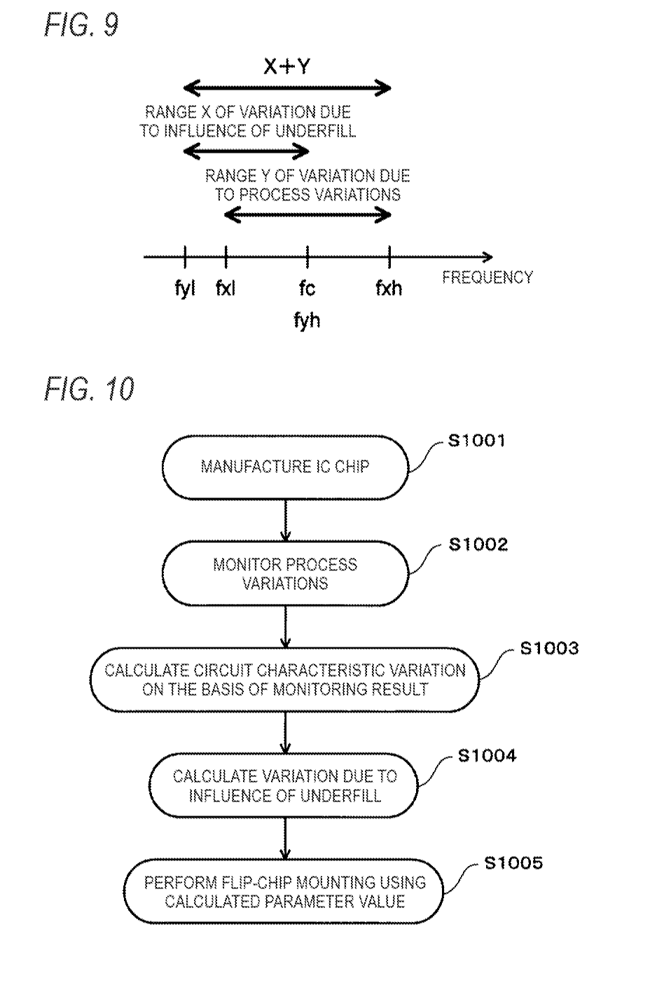

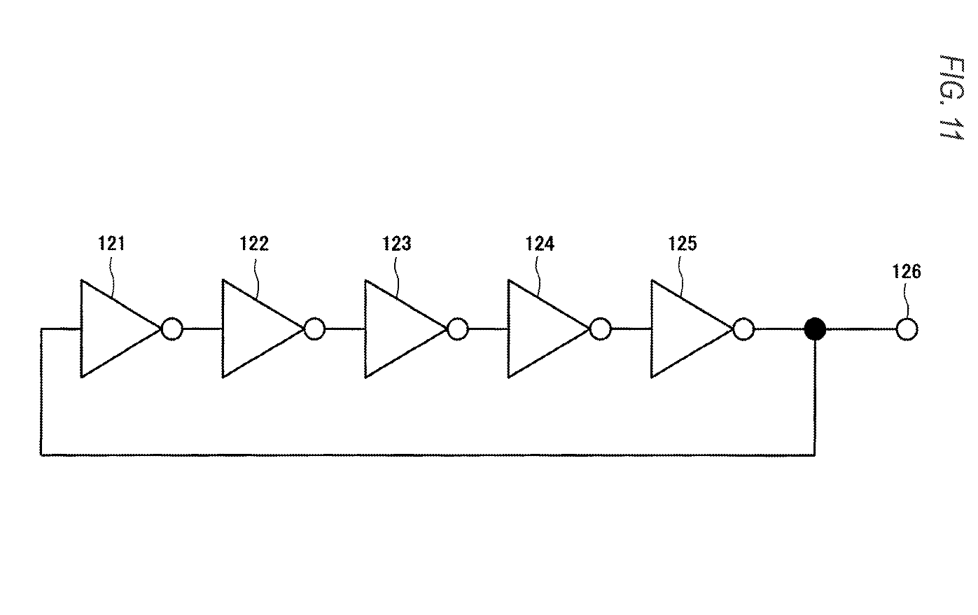

A manufacturing method of a wireless apparatus incorporating the power amplifier high-frequency IC chip 100 will be described below. First, FIG. 10 is a flowchart of a mounting process which includes selection of an underfill for compensating for a characteristic variation due to process variations.

A power amplifier high-frequency IC chip 100 is manufactured (step S1001) and process variations of the power amplifier high-frequency IC chip 100 are monitored (step S1002). For example, the threshold voltage Vth of a transistor is used as representing process variations.

A circuit characteristic variation amount is then calculated using the monitored process variations (step S1003). For example, the input reflection coefficient 811 and the output reflection coefficient 822 of a power amplifier are used as the circuit characteristic.

A variation amount due to the influence of an underfill for producing a desired circuit characteristic is then determined on the basis of the calculated circuit characteristic variation amount (step S1004). Finally, flip-flop mounting is performed using the thus-determined variation amount due to the influence of an underfill (step S1005). An underfill that is necessary for obtaining the desired circuit characteristic is selected by changing the relative permittivity of a resin or controlling the distance between the mounting board and the process variations detector 110 according to the variation amount due to the influence of an underfill determined at step S1005.

For example, let Vths represent a threshold voltage, obtained at step S1002, of the transistor that has been affected by process variations. A variation amount dfx of the notch frequency due to the process variations from the notch frequency fc of the case that the threshold voltage Vth of the transistor is at the center is calculated using the characteristic of the input reflection coefficient S11 and the output reflection coefficient 522 shown in FIG. 4.

Subsequently, a material having such a relative permittivity value Er that the notch frequency becomes equal to the desired frequency ft is selected according to the result of FIG. 7 using the notch frequency variation amount dfx.

A notch frequency variation amount dfy to be caused by the underfill is determined so as to cancel out the notch frequency variation amount dfx due to the process variations, and a material having a relative permittivity value Er corresponding to the determined notch frequency variation amount dfy is selected. Alternatively, a distance between the mounting board 105 and the power amplifier high-frequency IC chip 100 that corresponds to the determined variation amount dfy is determined.

As is understood from the above description, even if a characteristic variation due to process variations and a characteristic variation due to influence of an underfill occur, the circuit characteristic can be adjusted to a desired one by determining a mounting condition according to the flowchart of FIG. 10.

That is, a circuit characteristic variation amount due to process variations of the is monitored by the process variations detector 110, an underfill parameter value is calculated using the monitored circuit characteristic variation amount, and an underfill having the calculated parameter value is applied. With this configuration, a desired circuit characteristic can be obtained even if process variations occur and there exists influence of an underfill.

Although in this embodiment the process variations detector 110 monitors the threshold voltage Vth of a transistor, the disclosure is not limited to such a case. For example, the resistance of a resistor, the inductance of an inductor, or the capacitance of a capacitor may be monitored. For example, a polysilicon resistor can be used as the resistor.

In the first embodiment, in the process variations detector 110, the MOS transistor is formed separately from the MOS transistor 501 of the main circuit 101.

A modification is possible in which the MOS transistor 501 of the main circuit 101 is also used as a variations detecting circuit (process variations detector).

The other components may be formed in the same as in the wireless apparatus according to the first embodiment, whereby highly reliable detection of and compensation for process variations are enabled without incurring increase of the chip size.

An underfill parameter may be adjusted for a purpose other than compensation for process variations, such as capacitance adjustment in connection with a peripheral circuit.

### Embodiment 2

Next, a description will be made of an embodiment in which the circuit configuration of the variations detecting circuit is changed.

In this embodiment, a ring oscillator shown in FIG. 11 is used as the process variations detector 110 which constitutes the variation detecting circuit. The other components are the same as in the first embodiment and hence will not be described here.

Also in this embodiment, a variation amount of the threshold voltage Vth is detected by measuring a gate voltage vs. drain current characteristic of the process variations detector 110. A parameter value of an underfill to be used for mounting is determined according to the detected variation amount of the threshold voltage Vth. That is, a notch position (notch frequency) of the input reflection coefficient 811 and the output reflection coefficient 822 of the voltage amplifier can be estimated (see FIG. 4) by monitoring the threshold voltage Vth of the MOS transistor by the process variations detector 110.

As shown in FIG. 11, the ring oscillator is a series connection of an even number of inverters 121-125 and an output signal that is output from the output-side inverter 125 is fed back to the input-side inverter 121. When a power source voltage is applied to the inverter 121 of the ring oscillator, the ring oscillator oscillates at a frequency that depends on an operation delay time of the inverters and an output signal is output from the output terminal 126.

In the ring oscillator shown in FIG. 11, the operation delay time of the inverters varies depending on process variations. For example, if the threshold voltage Vth of the transistor decreases due to process variations, the operation delay time of the inverters becomes shorter and the oscillation frequency of the ring oscillator increases. Conversely, if the threshold voltage Vth of the transistor increases due to process variations, the operation delay time of the inverters becomes longer and the oscillation frequency of the ring oscillator lowers.

The threshold voltage Vth of the transistor can be obtained by monitoring the oscillation frequency of the ring oscillator. For example, a notch position (notch frequency) of the input reflection coefficient S11 and the output reflection coefficient S22 of the voltage amplifier shown in FIG. 2 can be estimated by monitoring the threshold voltage Vth of the transistor by the process variations detector 110.

Therefore, also in this embodiment, as in the first embodiment, a parameter value is calculated and a mounting condition for compensation for process variations is determined according to the flowchart of FIG. 10.

### Embodiment 3

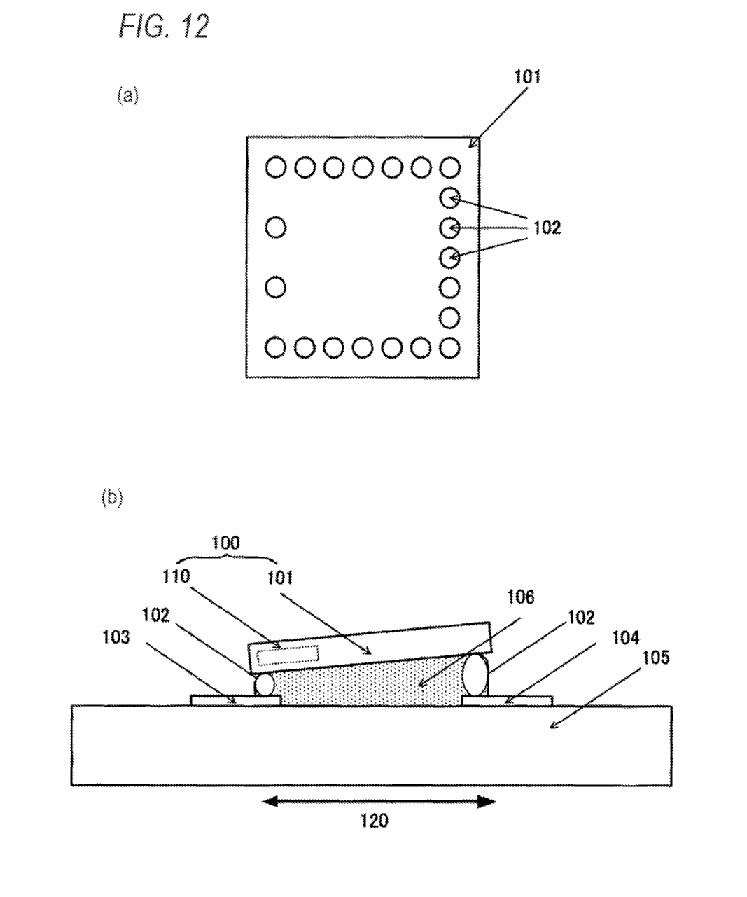

Next, a third embodiment of the disclosure will be described. FIG. 12(a) is a bottom view of a power amplifier IC chip which is part of a wireless apparatus according to a third embodiment of the disclosure. As shown in FIG. 12(a), bumps 102 are arranged asymmetrically on the bottom surface of the power amplifier high-frequency IC chip 100.

When the power amplifier high-frequency IC chip 100 is flip-chip-mounted on the mounting board 105, pressure is applied to the chip from above. Where the bumps are arranged asymmetrically as shown in FIG. 12(a), the pressure applied per bump is high in the region where the number of bumps is small. Therefore, as shown in a sectional view of FIG. 12(b), the distance between the mounting board and the power amplifier IC chip is short there.

Therefore, where the same pressure is applied to the entire power amplifier high-frequency IC chip 100, the underfill is made thin in the region where the number of bumps is small. Because of the structure with the asymmetrical bump arrangement, the degree of influence of the underfill on an electrical characteristic can be varied in an area 120 where the power amplifier high-frequency IC chip 100 is flip-chip-mounted.

For example, where power amplifiers are disposed at a left-hand position and a right-hand position in the power amplifier high-frequency IC chip 100 shown in FIGS. 12(a) and 12(b), the underfill is made thin and the parasitic capacitances are increased on the left side and the underfill is made thick and the parasitic capacitances are decreased on the right side. Therefore, as seen from FIG. 8, the notch frequency at which the input reflection coefficient S11 and the output reflection coefficient S22 of the left power amplifier are minimized lowers to a large extent. Therefore, the variation amount of the notch frequency of the input reflection coefficient S11 and the output reflection coefficient 522 of the right-hand power amplifier becomes smaller than that of the left-hand power amplifier.

Therefore, also in this embodiment, as in the first embodiment, a parameter value is calculated, a mounting condition is determined, and the bump arrangement is adjusted according to the flowchart of FIG. 10.

Next, a modification of the third embodiment of the disclosure will be described.

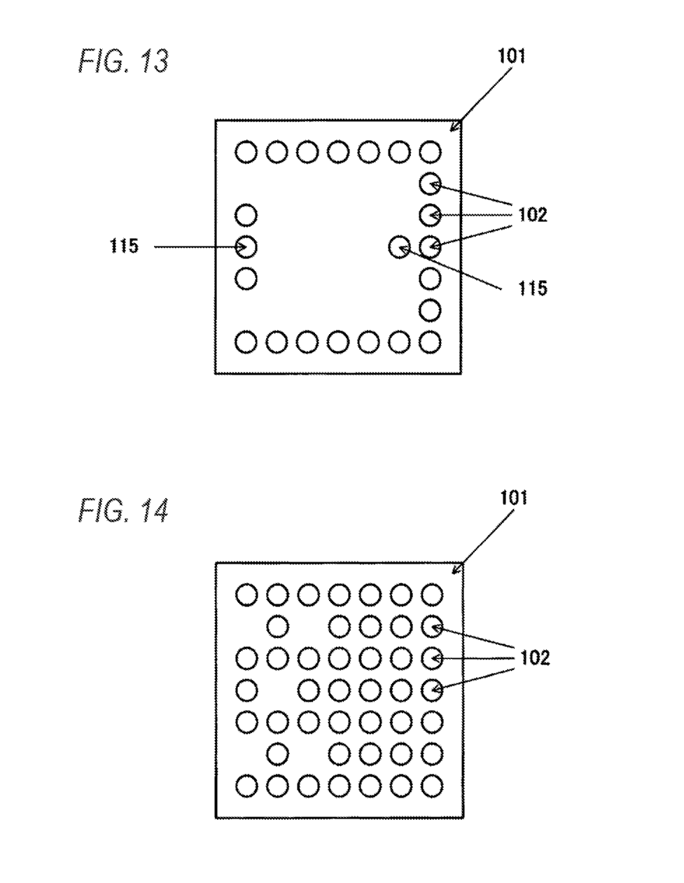

Usually, power amplifier IC chips are configured in such a manner that the number of bumps is minimized. However, to adjust the distance between the mounting board and the power amplifier IC chip or to make the distance distribution asymmetrical in the area 120 where the power amplifier high-frequency IC chip is flip-chip-mounted, spare bumps 115 are arranged in the manner shown in FIG. 13 in addition to the configuration of the power amplifier high-frequency IC chip 100 of the wireless apparatus according to the third embodiment.

The spare bumps 115 may be used as, for example, ground terminals of the circuit, whereby degradation of circuit characteristics can be suppressed.

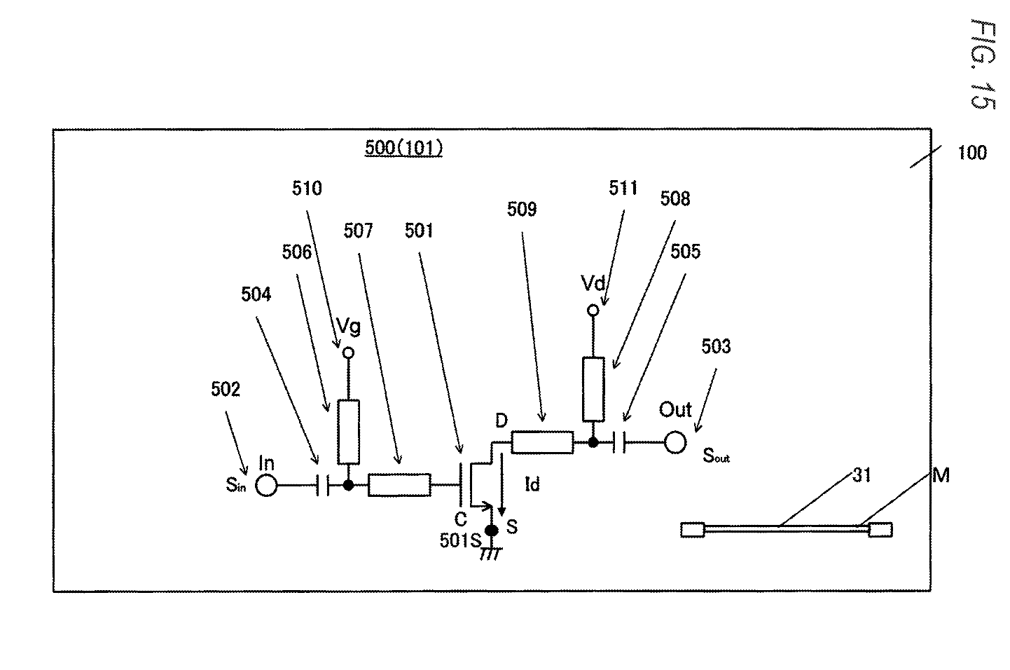

Although in this embodiment the bumps are arranged alongside the outer periphery in the manner shown in FIG. 12(a), the disclosure is not limited to such a case. For example, also in a structure in which as show in FIG. 14 bumps are arranged uniformly on the surface, to be placed on the mounting board, of the power amplifier high-frequency IC chip, the same advantage can be obtained by arranging the bumps 102 asymmetrically to make the distribution of the distance to the mounting board asymmetrical in the area 120 where the power amplifier high-frequency IC chip 100 is flip-chip-mounted.

Although in the embodiment the distribution of the distance to the mounting board 105 is made asymmetrical in the area 120 where the power amplifier high-frequency IC chip 100 is flip-chip-mounted by arranging the bumps asymmetrically, the thicknesses of the underfill may be adjusted in the area 120 where the power ampler high-frequency IC chip 100 is flip-chip-mounted instead of arranging the bumps asymmetrically.

For example, the pressure that is applied in a reflow process for mounting the power amplifier high-frequency IC chip 100 on the mounting board via the bumps may be adjusted. It suffices that in the step of mounting the power amplifier high-frequency IC chip 100 the thickness of the underfill which is placed between the power amplifier high-frequency IC chip 100 and the mounting board be varied in the area 120 where the power amplifier high-frequency IC chip 100 is flip-chip-mounted.

Therefore, also in this embodiment, as in the first embodiment, a parameter value is calculated and a mounting condition can be determined according to a flowchart as shown in FIG. 10.

### Embodiment 4

Next, a fourth embodiment of the disclosure will be described. Whereas in the first and second embodiments of the disclosure the transistor or the ring oscillator is used as an example of the process variations detector 110 to detect the threshold voltage Vth of the transistor, the fourth embodiment of the disclosure uses PCM (process control monitor) data as a detection value of the variations detector. PCM data are data (indicating a manufacturing result) that are used for the quality management of chips in the manufacture of power amplifier IC chips.

Conventionally, in manufacturing chips using a semiconductor process, to monitor the quality of chips, monitoring is done by forming various devices on the same wafer. For example, the threshold voltage Vth and the drain current Id of a transistor, the resistance of an aluminum or copper interconnection, and the resistance of polysilicon are monitored. The threshold voltage Vth is managed as PCM data with its lower limit, upper limit, and center value represented by FF, SS, and 17, respectively.

FIG. 15 shows the configuration of a chip. A main circuit 101 and a monitoring unit M are formed in a power amplifier high-frequency IC chip 100. A polysilicon resistor 31, for example, is formed in the monitoring unit M. A voltage across both ends of the polysilicon resistor 31 and a current flowing through it can be measured and hence its resistance can be calculated.

The resistance of the polysilicon resistor 31 is used among PCM data. If the resistance is large, it can be judged that a process variation that causes pattern width reduction has occurred.

That is, process variations can be monitored by using PCM data and an underfill parameter value can be calculated using a monitored numerical value in the same manner as in the first embodiment. Therefore, process variations can be compensated for by adjusting the parameter of the underfill that is used for mounting.

As a result, a desired circuit characteristic can be obtained even with process variations and influence of the underfill.

Although in the fourth embodiment the monitoring unit M is formed in each power amplifier high-frequency IC chip 100, it may be formed in each wafer W.

This method includes the steps of manufacturing a wafer having at least one process variations detector (at least one process variations detector is provided for each wafer) and plural high-frequency IC chip formation units each having a device unit that constitutes a main circuit; detecting a process variation using the process variations detector; dividing the wafer into plural high-frequency IC chips; adjusting an underfill parameter on the basis of data detected by the 1) detecting step; and mounting the high-frequency IC chip on a mounting board by applying an underfill having a parameter value obtained by the adjusting step.

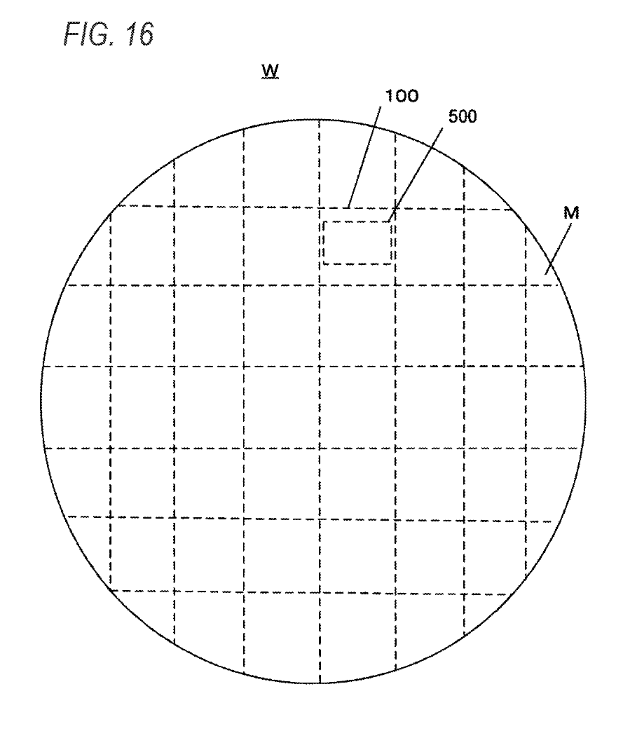

That is, as shown in FIG. 16, device units 500 in each of which a power amplifier high-frequency IC chip 100, for example, is formed and a monitoring unit M are formed on a wafer W at prescribed positions. A polysilicon resistor, for example, is formed in the monitoring unit. A voltage across both ends of the polysilicon resistor and a current flowing through it can be measured and hence its resistance can be calculated.

With the above configuration, as in the first embodiment, a desired circuit characteristic can be obtained even with process variations and influence of an underfill by calculating an underfill parameter value using a process variation value monitored using PCM data and applying an underfill having the calculated parameter value.

Unlike in the wireless apparatus according to the fourth embodiment, the power amplifier high-frequency IC chip 100 is not formed with the monitoring unit or the variations detector, which makes it possible to suppress chip area increase.

As described above, in a wireless apparatus in which a power amplifier high-frequency IC chip corresponding to a microwave/millimeter wave band high-frequency circuit is flip-chip-mounted on a mounting board, a circuit characteristic variation amount due to process variations occurring in manufacture of the power ampler high-frequency IC chip is monitored by the process variations detector, an underfill parameter is calculated using the monitored circuit characteristic variation amount, and an underfill made of a material or having a relative permittivity value corresponding to the calculated parameter value is applied. As a result, a wireless apparatus can be provided which exhibits a desired circuit characteristic because a frequency characteristic variation due to process variations and influence of the underfill is suppressed.

In particular, even greater advantages can be obtained in wireless apparatuses which perform wireless communication in the millimeter wave band because of high signal frequencies and great influence of the underfill.

That is, in this disclosure, it is not essential that the process variations detector be provided in the high-frequency IC chip. That is, a manufacturing method of a wireless apparatus may be employed which includes the steps of manufacturing a high-frequency IC chip having a device unit that constitutes a main circuit; detecting a process variation of the high-frequency IC chip using a process variations detector; and mounting the high-frequency IC chip on a mounting board by applying an underfill having a parameter value that corresponds to data by the detecting step.

Although the disclosure has been made in detail by referring to the particular embodiments, it is apparent to those skilled in the art that various changes and modifications are possible without departing from the spirit and scope of the disclosure.

The present application is based on Japanese Patent Application No. 2011-244970 filed on Nov. 8, 2011, the contents of which are incorporated herein by reference.

### INDUSTRIAL APPLICABILITY

As described above, this disclosure makes it possible to provide a semiconductor device having superior high-frequency characteristics in a wireless apparatus which performs wireless communication in high-frequency bands, in particular, microwave/millimeter wave bands.

### DESCRIPTION OF REFERENCE NUMERALS AND SIGNS

100: High-frequency IC chip (power amplifier high-frequency IC chip)
101: Main circuit
110: Process variations detector 110
102: Bump
103: Input terminal
104: Output terminal
105: Mounting board
106: Underfill
500: Device unit
501: Power amplification transistor
502: Input terminal
503: Output terminal
504, 505: DC block capacitor
506, 507: Input matching transmission line
508, 509: Output matching transmission line
510: Gate voltage terminal
511: Drain voltage terminal

1. A wireless apparatus comprising:
a mounting board;
a high-frequency IC chip which is flip-chip-mounted on the mounting board; and
an underfill which is applied between the high-frequency IC chip and the mounting board,
wherein the high-frequency IC chip includes a device unit which constitutes a main circuit and a process variations detector that detects a process variation of the high-frequency IC chip; and
wherein the underfill has a parameter value that corresponds to the detected process variation.

2. The wireless apparatus according to claim 1, wherein the process variations detector functions as part of the device unit.

3. The wireless apparatus according to claim 1, wherein the process variations detector is separated from the device unit in the high-frequency IC chip.

4. The wireless apparatus according to claim 1, wherein the process variations detector is formed by using a transistor.

5. The wireless apparatus according to claim 1, wherein the process variations detector is formed by using a ring oscillator.

6. The wireless apparatus according to claim 1, wherein the parameter value of the underfill is a relative permittivity value of a material that is applied as the underfill.

7. The wireless apparatus according to claim 1, wherein the parameter value of the underfill is a distance between the high-frequency IC chip and the mounting board.

8. The wireless apparatus according to claim 1, wherein the high-frequency IC chip is connected to the mounting board via bumps; and
wherein the bumps are arranged asymmetrically on the high-frequency IC chip.

9. The wireless apparatus according to claim 1, wherein the underfill applied between the high-frequency IC chip and the mounting board varies in thickness in an area where the high-frequency IC chip is flip-chip-mounted.

10. The wireless apparatus according to claim 1, wherein the process variations detector uses PCM (process control monitor) data.

11. The wireless apparatus according to claim 1, wherein the process variation is represented by a value that is measured before applying of the underfill.

12. A method for manufacturing a wireless apparatus, comprising the steps of:
manufacturing a high-frequency IC chip having a process variations detector and a device unit that constitutes a main circuit;
detecting a process variation of the high-frequency IC chip using the process variations detector; and
mounting the high-frequency IC chip on a mounting board by applying an underfill having a parameter value that corresponds to data detected by the detecting step.
